(19) United States
(12) Patent Application Publication
(10) Pub. No.: US 2005/0073872 A1
(43) Pub. Date: Apr. 7, 2005

(54) Cmos interface circuit

(76) Inventor: Takashi Suzuki, Chiba-ken (JP)

Correspondence Address: Takashi Suzuki, 272 Kan'no Yamada-machi, Katori-gun Chiba-ken, 289-0408, JP

(21) Appl. No.: 10/481,203

(22) PCT Filed: Jul. 23, 2002
(86) PCT No.: PCT/JP02/07414

(30) Foreign Application Priority Data
Jul. 27, 2001 (WO) PCT/JP01/06481

(51) Int. Cl. G11C 11/00

(52) U.S. Cl. 365/154

(57) ABSTRACT

This invention is about interface circuits of a CMOS device, for high speed data transfer of the CMOS device (1)(4) by inputting signal (2) (clock for a synchronous circuit, strobe, write signal for memory, other control signal and data) to a flip-flop (3) triggering at negative edge, and applied to the interface of synchronous bus, memory and other devices with other circuits.

### FIELD OF THE INVENTION

This invention relates to CMOS circuits for speeding up interface of a device. It is applied to bus interface, interface of memory and interface to other devices.

### BACKGROUND OF THE INVENTION

Heretofore, it is researched to be high performance of a electronic equipment like a personal computer by CMOS circuits. It is easy to speed up in a device, so speeding up interface between devices is required.

Double rate data transfer has been performed by transmitting at both edge of strobe. Fourfold rate data transfer has been performed with two clocks. But the usage of them is limited, because of difficulty of making a timing.

About memory, though a circuit setting memory cell arrays in parallel is known as U.S. Pat. No. 6,246,635, it is needed to be simple structure and speed-up as memory for cash.

And about synchronous bus, it is possible to speed up by changing clock frequency. Circuits for changing clock frequency are known as Japanese Patent No. H04-58048 and U.S. Pat. No. 6,246,635, but it is needed to use in synchronous bus by reducing phase fluctuation of frequency element.

Therefore, the purpose of this invention is high speed interface of a CMOS device with simple circuits.

### SUMMARY OF THE INVENTION

Usually about a synchronous circuit, there sets a flip-flop in data input section as a synchronizer. In this invention, by setting a flip-flop triggering at negative edge, high speed data transfer is realized. A flip-flop inputted signals structures a circuit in each case of considerable trigger: 1. clock for a synchronous circuit, 2. strobe, 3. control signal like write signal, 4. data for a counter circuit.

And it is possible to deal with data by adding a multiplexer in many kinds of circuits.

And for realization of high speed data transfer, there are improvements to a clock circuit and a multiplexer circuit.

### BRIEF DESCRIPTION OF THE DRAWINGS

FIG. 1 is a circuit set a flip-flop for keeping input data at negative edge to a circuit dealing with the input data;

FIG. 2 is a circuit added a circuit for dealing with input data to the circuit of FIG. 1;

FIG. 3 is a circuit added a multiplexer for selecting from input data and output of the flip-flop to the circuit of FIG. 1;

FIG. 4 is a circuit added a flip-flop for keeping the input data at positive edge to the circuit of FIG. 3;

FIG. 5 and FIG. 6 show a circuit and a wave form for fourfold rate data transfer with two clocks 90 degrees different in phase;

FIG. 7 is a circuit for fourfold rate data transfer by a multiplexer selecting double frequency clock;

FIG. 8 is a circuit dividing input clock by a synchronous counter and selecting frequency of output clock by a multiplexer;

FIG. 9 and FIG. 10 are memory circuits set flip-flops for keeping input data with strobe;

FIG. 11 is a memory circuit added a multiplexer for selecting from input data and output data of the memory to the circuit of FIG. 10;

FIG. 12 is a memory circuit set flip-flops for keeping input data at both edge of strobe;

FIG. 13 is a multiplexer circuit combined select signal and output enable signal with each input data;

FIG. 14 is a communication circuit for transmitting data by two lines with two counters; and

FIG. 15 is a whole figure of this invention applied to a device.

### DETAILED DESCRIPTION OF THE INVENTION

This refers more particularly to this invention with the figures.

In this invention as FIG. 1, there sets a flip-flop 3 keeping input data at negative edge of signal 2 in data input section of a circuit 1 dealing with the input data with the signal 2 (which is clock for a synchronous circuit, write signal for memory, strobe or control signal for some devices). By this, double rate data transfer or multi channel data transfer is realized by holding data line in common, because occupation of the data line is only while the signal 2 is in H level.

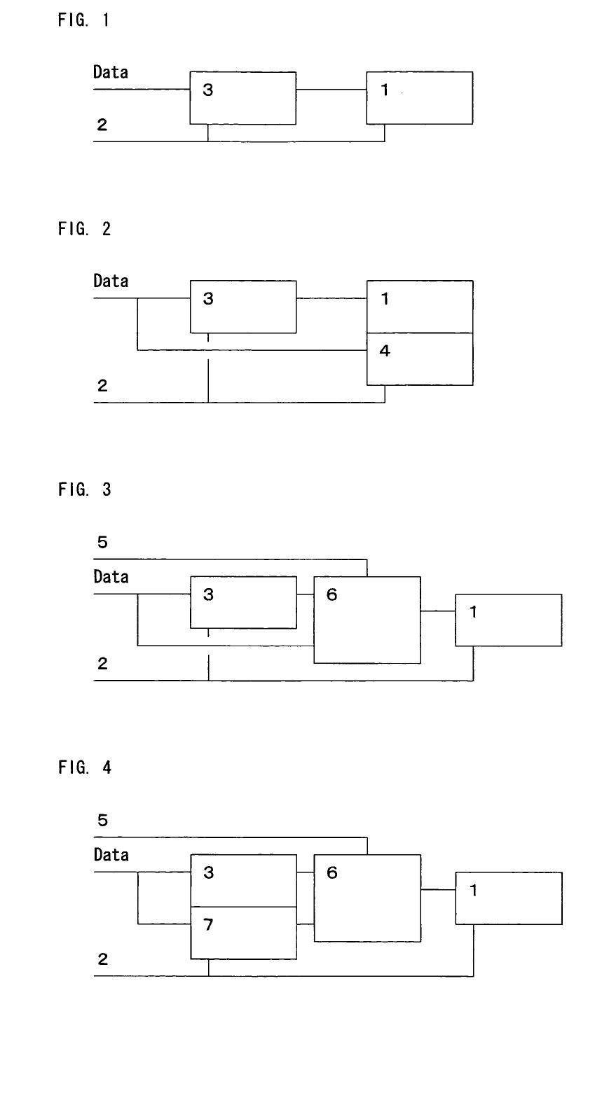

In FIG. 2, a circuit 4 dealing with input data with the signal 2 is added to the circuit of FIG. 1. Double bit width data of which upper bit is data while the signal 2 is in H level and of which lower bit is data while the signal 2 is in L level is dealt with if the circuit 1 and the circuit 4 are given same control signal, so double rate data transfer is realized by applying to synchronous bus, an SRAM and an SDRAM, and a double bit width device is realized by applying to a DAC. And in asynchronous serial communication, communication of the same speed as clock frequency is realized by combination of parity check and check sum. If the circuit 1 and the circuit 4 are given respective control signals, multi channel data transfer of synchronous bus is realized by outputting data from standardized bus buffers, because the data while the signal 2 is in H level and the data while the signal 2 is in L level are dealt with respectively. It is possible that the circuit 1 and the circuit 4 are different circuits at all, too.

In FIG. 3, by adding a multiplexer 6 for selecting from input data and output data of the flip-flop 3 with select signal 5 to the circuit of FIG. 1, one of the two data is dealt with. Multi channel data transfer is realized by applying to synchronous serial communication.

In FIG. 4, a flip-flop 7 triggering at positive edge is added to the circuit of FIG. 3 to keep the input data at both edge of the signal 2. If the circuit is applied to a command and address decode circuit of synchronous bus, high speed bus is realized, because timing of dealing with command and address can be earlier by a multiplexer 6 selecting with high rate data transfer signal as select signal 5. Here, it is necessary to be more careful about select timing of the multiplexer 6 because the flip-flop 3 and the flip-flop 7 works as a synchronizer of the circuit 1, and about difference of timing dealing with the input data to the circuit of FIG. 3 if there is a synchronizer in the circuit 1.

Further, bus interface, interface of memory and interface (serial communication mainly) to other devices are improved to realize high speed data transfer.

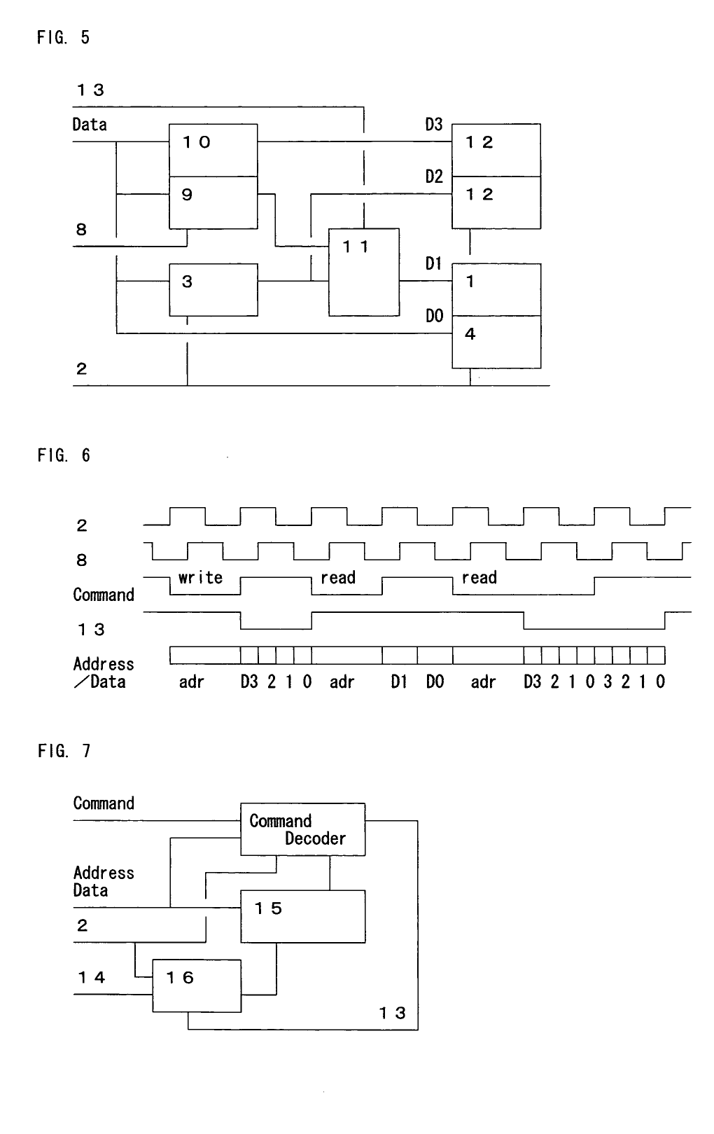

About synchronous bus as FIG. 5 and FIG. 6, fourfold rate data transfer is realized by two clocks 2,8 which are 90 degrees different in phase. Flip-flops 9,10 keeping input data at both edge of the clock 8 which is 90 degrees late in phase are added to the circuit of FIG. 2. This fourfold bit width data is dealt with by circuits 1,4,12 with clock 2. In case of the fourfold rate data transfer, data is selected by a multiplexer 11 with fourfold rate data transfer signal 13 for ordering of the data transfer as data kept by the flip-flop 3 is dealt with by the circuit 12 and data kept by the flip-flop 9 is dealt with by the circuit 1. FIG. 6 shows the wave form.

As FIG. 7, fourfold rate data transfer is realized by using double frequency clock 14, too. The command and address decode circuit explained with FIG. 4 uses normal clock 2 and the double rate data transfer circuit 15 explained with FIG. 2 uses selected one from the normal clock 2 and the double frequency clock 14 by a multiplexer 16 with the fourfold rate data transfer signal 13.

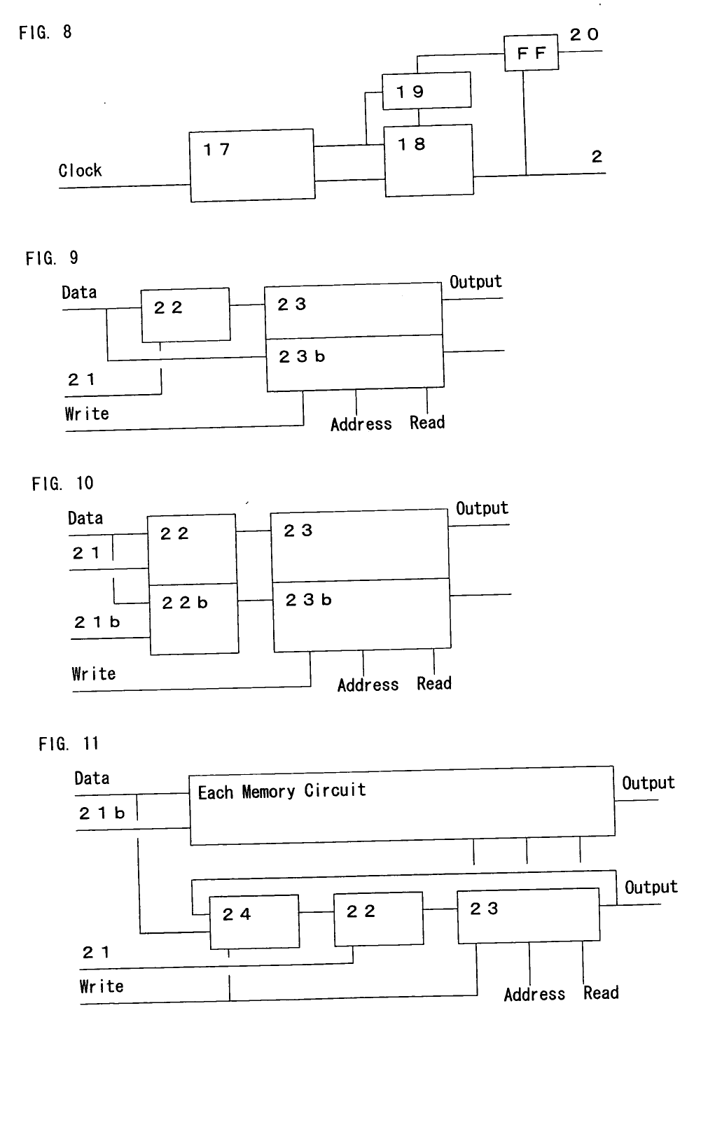

And by a circuit of FIG. 8, it is possible to speed up by selecting clock frequency of whole bus. Divided clocks outputted from a synchronous binary counter 17 are inputted to a multiplexer 18. Select signal 20 is synchronized by a flip-flop 19 with lowest frequency clock outputted from the synchronous binary counter 17 and frequency of output clock 2 is selected by the multiplexer 18. It is possible to reduce phase fluctuation of frequency element of the output clock 2 to minimum by this circuit.

Next, think about memory circuits.

In case of writing to an SRAM, it is enough to input writing data after controlling address and write signal, so it is possible to write to the memory for cash in high speed by a simple circuit only keeping the data. As FIG. 9, after setting address, write signal and data, the data is kept by a flip-flop 22 with strobe 21. After setting next data and writing to memory cell arrays 23,23b, it is enough to turn back the write signal. Be careful about adding the strobe 21 to the circuit of FIG. 2, here.

And as FIG. 10, combinations of the strobe 21, the flip-flop 22 and the memory cell array 23 are set in parallel. After setting data, the data is kept by the flip-flop 22 with the strobe 21. By repeating this, writing to the memory cell arrays 23 is done.

Though all data must be written in the circuit of previous figure, in case of writing partly as FIG. 11, a multiplexer 24 inputted input data and output data is added to each combination of the strobe 21, the flip-flop 22 and the memory cell array 23. After the output data which is fed back by reading the memory cell array 23 and which is out of rewrite is kept by the flip-flop 22 with the strobe 21, output of the multiplexer 24 is selected the input data with the write signal and the input data for writing is kept by the flip-flop 22 with the strobe 21 and is written.

And writing by double rate data transfer with the strobe 21 is realized, too. As FIG. 12, flip-flops 22,25 are set to keep data at both edge of the strobe 21. Data is kept by the flip-flop 22 with the strobe 21 after setting the address, the write signal and the data, and next data is kept by the flip-flop 25 with return of the strobe 21 after setting the next data. After writing a suit of the data to the memory cell arrays 23,23b, it is enough to turn back the write signal.

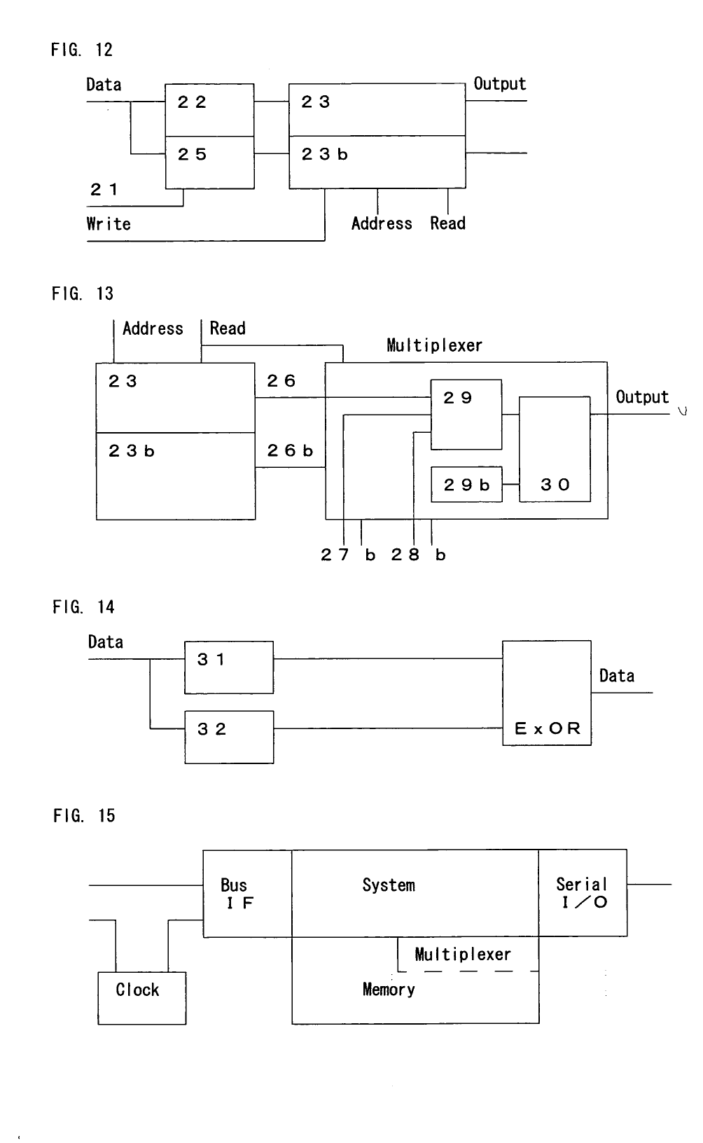

As FIG. 13, data from memory cell arrays 23 is output by a multiplexer, so speed-up of a multiplexer is designed. A combination of select signal 27 and output enable signal 28 for each data 26 is inputted to an AND gate 29. Outputs of each AND gate 29 are inputted to an OR gate 30, and the data is outputted. It is a 3 input AND-OR gate inputted the data 26, the select signal 27 and the output enable signal 28.

At last it is considered about interface (serial communication mainly) to other device.

As FIG. 14, it is designed to speed up by dividing a signal line into two lines. Data is inputted to a counter 31 (structured by a flip-flop triggering at negative edge) working at negative edge of input signal and a counter 32 (structured by a flip-flop triggering at positive edge) working at positive edge of the input signal, and divided outputs from the two counters 31,32 are transmitted to a device of receive side by two lines. In the device of receive side, the original data is gotten by inputting the data of the two lines to an exclusive OR gate.

### POSSIBILITY OF INDUSTRIAL USAGE

As FIG. 15, it is possible to speed up interface of a device by applying this invention to clock supply section of synchronous bus, bus interface section of the device, interface section of memory and interface section of serial communication.

1. A circuit for dealing with input data comprising: a flip-flop (3) for keeping input data at negative edge of signal (2); and means (1) for dealing with output of said flip-flop (3) with the signal (2).

2. The circuit claimed in claim 1, further comprising:
second means (4) for dealing with input data with the signal (2).

3. The circuit claimed in claim 1, further comprising:
a multiplexer (6) for selecting from input data and the output of said flip-flop (3).

4. The circuit claimed in claim 3, further comprising:
a second flip-flop (7) for keeping the input data at positive edge of the signal (2) and for outputting to said multiplexer (6).

5. A fourfold rate data transfer circuit including:
said circuit claimed in claim 2; and
a multiplexer (16) for selecting from the signal (2) of clock and double frequency clock (14).

6. A fourfold rate data transfer circuit including:
said circuit claimed in claim 2;
a second flip-flop (9) and a third flip-flop (10) for keeping input data at negative edge and at positive edge of clock (8) 90 degrees different in phase from the signal (2) of clock;
a multiplexer (11) for selecting from the output of said flip-flop (3) and output of said second flip-flop (9) and for outputting to said means (1); and
third means (12) for dealing with the output of said flip-flop (3) and output of said third flip-flop (10) with the signal (2) of clock.

7. A memory circuit comprising:
a flip-flop (22) for keeping input data with strobe (21); and
a memory cell array (23) for storing output of said flip-flop (22) and a second memory cell array (23b) for storing input data controlled by common address and common control signal.

8. The memory circuit claimed in claim 7, further comprising:
a second flip-flop (22b) for keeping the input data with second strobe (21b) and for outputting to said second memory cell array (23b).

9. The memory circuit claimed in claim 8, further comprising:
about each set of the strobe (21), said flip-flop (22) and said memory cell array (23), a multiplexer (24) for selecting from the input data and output data of each said memory cell array (23) and for outputting write data to each said flip-flop (22).

10. The memory circuit claimed in claim 7, further comprising:
a second flip-flop (25) for keeping the input data at reverse edge of the strobe (21) to said flip-flop (22) and for outputting to said second memory cell array (23b).

11. A data transmitting circuit comprising:
a counter (31) including a flip-flop triggering at negative edge of data for outputting binary divided data; and
a second counter (32) including a second flip-flop triggering at positive edge of the data for outputting second binary divided data.

12. A clock circuit comprising:
a synchronous counter (17) for dividing input clock and for outputting divided clocks different in frequency;
a flip-flop (19) for synchronizing select signal (20) with the divided clock of lowest frequency and for outputting synchronized select signal; and
a multiplexer (18) for selecting from the divided clocks with the synchronized select signal and for outputting selected clock.

13. A multiplexer circuit comprising:
a gate (29) inputted input data (26), select signal (27) and output enable signal (28) for selecting about each the input data (26); and
a second gate (30) inputted output of each said gate (29) for outputting output data.
